(19) United States
(12) Patent Application Publication
(10) Pub. No.: US 2025/0086344 A1
(43) Pub. Date: Mar. 13, 2025

(54) FUNCTION BLOCK TEMPLATE

(71) Applicant: YOKOGAWA ELECTRIC CORPORATION, Tokyo (JP)

(72) Inventors: Jati SANTOSO, Singapore (SG); Thye Guan TAN, Singapore (SG); Thanh Trung BUI, Ho Chi Minh city (VN)

(21) Appl. No.: 18/244,813

(22) Filed: Sep. 11, 2023

(51) Int. Cl. G06F 30/20

(52) U.S. Cl. CPC G06F 30/20

(57) ABSTRACT

A device may access a database of devices, wherein the database comprises a plurality of templates, and wherein each of the plurality of templates comprises asset-related information and a plurality of predefined algorithms. The device may provide a graphical user interface for a user to input information related to a targeted device. The device may automatically select a targeted operation template among the plurality of templates for the asset in response to either the input information or a change of condition of a neighboring device connected to the targeted device. The device may automatically modify one of the plurality of predefined algorithms that is associated with the targeted operation template based on a peripheral device associated with the asset for an optimization purpose. The device may calculate asset performance indicators as a measure to determine how far the optimization purpose has been achieved.

### FIELD OF THE DISCLOSURE

The invention relates generally to systems and methods for controlling and managing industrial assets and particularly to automatically determining operational characteristics for a selected industrial asset.

### BACKGROUND

Industrial assets (or more simply, “assets”) comprise controllable elements (e.g., motors, actuators, magnetic field generators, electrical current generators/transformers, etc.) in order to perform at least one aspect of an industrial process. Such assets may be embodied as chillers, pumps, boilers, blowers, compressors, etc. Controlling assets may be essential to effectively and efficiently executing an industrial process (e.g., producing a chemical, manufacturing a product, distilling petroleum, commercial baking/cooking, etc.). Often an asset is monitored to ensure that the asset operates in accordance with the design specification (e.g. within a set of desired parameter values). Such parameters may be static throughout an industrial process or may vary, such as to operate differently at various stages of the industrial process and/or produce a static output even as feed stock or environmental or operational conditions change. Additionally, parameters for one asset may be affected by other events, such as the addition, removal, or reconfiguration of other assets or a change in operation of the asset (e.g., utilizing a different feed stock and/or changing the output product).

Managing assets can be resource intensive and error prone. This is further exacerbated when the asset's operation, or a change in operation, is time sensitive.

### SUMMARY

Determining the parameters for an asset can be a complex task. In the case of a chiller there is a heat sink (e.g., air, air-water evaporator, etc.), a heat source to be cooled, a power input, and variations of any one or more of the foregoing. For example, the material to be cooled may be flowing in a pipe having an adjustable flow rate. In order to maximize production, it may be beneficial to set the flow rate to as high as possible. However, the chiller's operational parameters may need to be configured in order to accommodate the flow rate, as well as any other changes (e.g., change in air temperature, other equipment affecting the efficiency of the chiller, etc.). The calculations become more challenging if there is a significant change, such as the material to be cooled is changed and/or the rate of cooling is critical, which may or may not be constant. The material to be cooled may be static (e.g., in a tank or other storage vessel) or dynamic (e.g., flowing in a pipe, transported on a conveyor, etc.). The material to be cooled may also be simultaneously subject to other operations that may or may not be constant, such as mixing with other materials at a different temperature, endothermic or exothermic reactions, compression, expansion, state change, etc. These other operations further complicate calculations required to determine the operational characteristics of the chiller in order to produce the desired result.

The complexity of determining operational parameters (identified above) illustrates only a portion of those that may be required, namely an asset such as a chiller, operating as a solitary component. As a part of a subsystem (e.g., a collection of chillers) or a larger system (e.g., a facility with other assets), additional or alternative calculations may be required. For example, if a chiller is operated in proximity to another asset that generates a lot of heat (e.g., oven, smelting crucible, cracking tower, etc.), the operation on the chiller may need to be altered based on such a source of heat starting or stopping. When part of a subsystem of chillers, a single chiller may need to be operated to accommodate another chiller starting or stopping or altering its own operational parameters. The calculations of an asset's operational parameters may also need to accommodate the addition and/or removal of other equipment, such as due to a failure (partial or total), replacement/refurbishment, removal, or addition of the other equipment.

These and other needs are addressed by the various embodiments and configurations of the present invention. The present invention can provide a number of advantages depending on the particular configuration. These and other advantages will be apparent from the disclosure of the invention(s) contained herein.

Embodiments herein are generally directed to systems and methods to automate and optimize asset operations and perform related data calculations for various asset types. The asset types are variously embodied as industrial assets, such as those comprising at least one controllable element (e.g., motor, actuator, heater, cooler, electromagnetic generator/converter, etc.) and including, but not limited to, heaters, chillers, pumps, boilers, blowers, solar collectors, and compressors. In one embodiment, a database is provided that further comprises a plurality of templates, each template having asset-related information and one or more predefined algorithms. Information related to targeted device(s) is input, such as through a graphical user interface (GUI), to identify the targeted device (e.g., type, model, serial number, etc.) and, therefrom, a corresponding template is automatically selected. In another embodiment, a peripheral device is associated with the asset and used to optimize the asset's operation. The inputs from the peripheral devices may then be used to automatically modify one or more of the plurality of predefined algorithms associated with the selected template. The modifications to one or more of the plurality of predefined algorithms are selected from a sub-set of algorithms and automatically combined to form a combined algorithm. The key performance indictors (KPIs) are determined for the asset based on utilization of the combined algorithm(s). Thereafter, observational data may be utilized to then calculate subsequent asset performance indicators to determine amount of optimization achieved.

In some aspects, the techniques described herein relate to a method of monitoring an asset, including: accessing a database of devices, wherein the database includes a plurality of templates, and wherein each of the plurality of templates includes an asset type related information and a plurality of predefined algorithms; providing a graphical user interface for a user to input information related to a targeted device; automatically selecting a targeted operation template among the plurality of templates for the asset in response to either the input information or a change of condition of a neighboring device connected to the targeted device; automatically modifying one of the plurality of predefined algorithms that is associated with the targeted operation template based on a peripheral device associated with the asset for an optimization purpose; and calculating asset performance indicators as a measure to determine how far the optimization purpose has been achieved.

In some aspects, the techniques described herein relate to a method, wherein the asset type includes an industrial component.

In some aspects, the techniques described herein relate to a method, wherein the industrial component includes a controllable physical portion further including at least one of a motor, an actuator, a magnetic field generator, and an electrical current generator.

In some aspects, the techniques described herein relate to a method, wherein the industrial component includes at least one of a chiller, a pump, a boiler, a blower, and a compressor.

In some aspects, the techniques described herein relate to a method, wherein each of the plurality of predefined algorithms is associated with a plurality of parameters including at least one of: chiller power, chilled water supply temperature, chilled water return temperature, or chilled water flow, when the asset type is a chiller.

In some aspects, the techniques described herein relate to a method, wherein at least two of the plurality of predefined algorithms is associated with a plurality of parameters including at least one of: discharge pressure, discharge flow, wet well level, and pump power, when the asset type is a pump.

In some aspects, the techniques described herein relate to a method, wherein automatically modifying one of the plurality of predefined algorithms that is associated with the targeted operation template includes: selecting a sub-set of predefined algorithms among the plurality of predefined algorithms, and automatically combining the sub-set of predefined algorithms to form a combined algorithm, wherein the combined algorithm is associated with performance of a second asset, wherein the second asset is associated with the asset.

In some aspects, the techniques described herein relate to a method, wherein selecting a sub-set of predefined algorithms among the plurality of predefined algorithms includes: identifying one or more correlations among the plurality of predefined algorithms, and selecting a sub-set of predefined algorithms bases on the one or more correlations, wherein the sub-set of predefined algorithms are correlated.

In some aspects, the techniques described herein relate to a method, wherein the peripheral device includes at least one of: a sensor associated with the asset, an instrument associated with the asset, an algorithm associated with the asset, cloud data associated with the asset, or server data associated with the asset, and wherein the peripheral device provides a plurality of values associated with a plurality of parameters of the asset.

In some aspects, the techniques described herein relate to a method, wherein automatically modifying one of the plurality of predefined algorithms that is associated with the targeted operation template includes: obtaining the plurality of values associated with the plurality of parameters of the asset from the peripheral device, identifying one or more correlations among the plurality of parameters, and modifying one or more coefficients associated with the plurality of predefined algorithms based on the one or more correlations and the plurality of values.

In some aspects, the techniques described herein relate to a method, further including: receiving, via the graphical user interface, a user input associated with grouping a plurality of devices, specifically, the plurality of devices may operate in groups based on the equipment/device type and/or function (e.g. rotating equipment such as centrifugal pumps may operate in groups, in association with an industrial process); and assigning the plurality of devices to the asset based on the user input.

In some aspects, the techniques described herein relate to a system, including: an input component to receive the selection of a function block from a number of function blocks; a processor to, in accordance with the selection of the function block, automatically select a template, from a number of templates, and an algorithm, from a number of algorithms, wherein the template maps data inputs to the algorithm to outputs produced by the algorithm; upon determining a difference between at least one of the template and the algorithm, to at least one of an asset-specific template or an asset-specific algorithm, modifying the corresponding at least one template or algorithm of the function block; and the processor then causing an industrial asset to be operated in accordance with the function block.

In some aspects, the techniques described herein relate to a system, further including: a peripheral device in communication with the industrial asset; and wherein the processor is a portion of the peripheral device.

In some aspects, the techniques described herein relate to a method, including: receiving a selection of a function block for an asset; selecting a template and a predefined algorithm for controlling and maintaining the asset based on receiving the selection of the function block for the asset; mapping an input to the asset with output data for the asset; cross-checking the function block to at least one of a model indicator and type indicator to confirm that the function block matches the selected template and the selected predefined algorithm; and modifying the function block to better fit the asset based on the cross-checking.

In some aspects, the techniques described herein relate to a method, wherein the asset includes at least one of a chiller, pump, boiler, blower, and compressor.

In some aspects, the techniques described herein relate to a method, further including: confirming the modified function block better matches at least one Key Performance Indicator (KPI) of the asset as compared to the function block prior to modifying the function block; and storing the modified function block in a database with an association that links the modified function block to the function block.

In some aspects, the techniques described herein relate to a method, wherein the at least one KPI includes at least one of pressure, discharge flow, wet well level, power, energy consumption value, and carbon dioxide emissions.

In some aspects, the techniques described herein relate to a method, further including: populating a user dashboard with a KPI of the asset according to at least one of the function block and the modified function block; and receiving a user input via the dashboard, wherein the user input indicates which of the function block and modified function block is preferred to use in connection with the asset.

In some aspects, the techniques described herein relate to a method, wherein the function block is selected from a function block template library that stores a plurality of templates for a plurality of different assets and asset types.

In some aspects, the techniques described herein relate to a method, wherein the function block is displayed via a user interface along with one or more automatically-suggested input parameters for the asset.

A system on a chip (SoC) including any one or more of the above aspects or aspects of the embodiments described herein.

One or more means for performing any one or more of the above aspects or aspects of the embodiments described herein.

Any aspect in combination with any one or more other aspects.

Any one or more of the features disclosed herein.

Any one or more of the features as substantially disclosed herein.

Any one or more of the features as substantially disclosed herein in combination with any one or more other features as substantially disclosed herein.

Any one of the aspects/features/embodiments in combination with any one or more other aspects/features/embodiments.

Use of any one or more of the aspects or features as disclosed herein.

Any of the above aspects, wherein the data storage comprises a non-transitory storage device, which may further comprise at least one of: an on-chip memory within the processor, a register of the processor, an on-board memory co-located on a processing board with the processor, a memory accessible to the processor via a bus, a magnetic media, an optical media, a solid-state media, an input-output buffer, a memory of an input-output component in communication with the processor, a network communication buffer, and a networked component in communication with the processor via a network interface.

It is to be appreciated that any feature described herein can be claimed in combination with any other feature(s) as described herein, regardless of whether the features come from the same described embodiment.

The phrases “at least one,” “one or more,” “or,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B, and C together.

The term “a” or “an” entity refers to one or more of that entity. As such, the terms “a” (or “an”), “one or more,” and “at least one” can be used interchangeably herein. It is also to be noted that the terms “comprising,” “including,” and “having” can be used interchangeably.

The term “automatic” and variations thereof, as used herein, refers to any process or operation, which is typically continuous or semi-continuous, done without material human input when the process or operation is performed. However, a process or operation can be automatic, even though performance of the process or operation uses material or immaterial human input, if the input is received before performance of the process or operation. Human input is deemed to be material if such input influences how the process or operation will be performed. Human input that consents to the performance of the process or operation is not deemed to be “material.”

Aspects of the present disclosure may take the form of an embodiment that is entirely hardware, an embodiment that is entirely software (including firmware, resident software, micro-code, etc.) or an embodiment combining software and hardware aspects that may all generally be referred to herein as a “circuit,” “module,” or “system.” Any combination of one or more computer-readable medium(s) may be utilized. The computer-readable medium may be a computer-readable signal medium or a computer-readable storage medium.

A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer-readable storage medium may be any tangible, non-transitory medium that can contain or store a program for use by or in connection with an instruction execution system, apparatus, or device.

A computer-readable signal medium may include a propagated data signal with computer-readable program code embodied therein, for example, in baseband or as part of a carrier wave. Such a propagated signal may take any of a variety of forms, including, but not limited to, electro-magnetic, optical, or any suitable combination thereof. A computer-readable signal medium may be any computer-readable medium that is not a computer-readable storage medium and that can communicate, propagate, or transport a program for use by or in connection with an instruction execution system, apparatus, or device. Program code embodied on a computer-readable medium may be transmitted using any appropriate medium, including, but not limited to, wireless, wireline, optical fiber cable, RF, etc., or any suitable combination of the foregoing.

The terms “determine,” “calculate,” “compute,” and variations thereof, as used herein, are used interchangeably and include any type of methodology, process, mathematical operation or technique.

The term “means” as used herein shall be given its broadest possible interpretation in accordance with 35 U.S.C., Section 112 (f) and/or Section 112, Paragraph 6. Accordingly, a claim incorporating the term “means” shall cover all structures, materials, or acts set forth herein, and all of the equivalents thereof. Further, the structures, materials or acts and the equivalents thereof shall include all those described in the summary, brief description of the drawings, detailed description, abstract, and claims themselves.

The preceding is a simplified summary of the invention to provide an understanding of some aspects of the invention. This summary is neither an extensive nor exhaustive overview of the invention and its various embodiments. It is intended neither to identify key or critical elements of the invention nor to delineate the scope of the invention but to present selected concepts of the invention in a simplified form as an introduction to the more detailed description presented below. As will be appreciated, other embodiments of the invention are possible utilizing, alone or in combination, one or more of the features set forth above or described in detail below. Also, while the disclosure is presented in terms of exemplary embodiments, it should be appreciated that an individual aspect of the disclosure can be separately claimed.

### BRIEF DESCRIPTION OF THE DRAWINGS

The present disclosure is described in conjunction with the appended figures:

FIG. 1 depicts a system in accordance with embodiments of the present disclosure;

FIG. 2 depicts a data flow in accordance with embodiments of the present disclosure;

FIG. 3 depicts a data flow in accordance with embodiments of the present disclosure;

FIG. 4 depicts a data flow in accordance with embodiments of the present disclosure;

FIG. 5 depicts a process in accordance with embodiments of the present disclosure;

FIG. 6 depicts a graphical user interface in accordance with embodiments of the present disclosure; and

FIG. 7 depicts a system in accordance with embodiments of the present disclosure.

### DETAILED DESCRIPTION

The ensuing description provides embodiments only and is not intended to limit the scope, applicability, or configuration of the claims. Rather, the ensuing description will provide those skilled in the art with an enabling description for implementing the embodiments. It will be understood that various changes may be made in the function and arrangement of elements without departing from the spirit and scope of the appended claims.

Any reference in the description comprising a numeric reference number, without an alphabetic sub-reference identifier when a sub-reference identifier exists in the figures, when used in the plural, is a reference to any two or more elements with the like reference number. When such a reference is made in the singular form, but without identification of the sub-reference identifier, it is a reference to one of the like numbered elements, but without limitation as to the particular one of the elements being referenced. Any explicit usage herein to the contrary or providing further qualification or identification shall take precedence.

The exemplary systems and methods of this disclosure will also be described in relation to analysis software, modules, and associated analysis hardware. However, to avoid unnecessarily obscuring the present disclosure, the following description omits well-known structures, components, and devices, which may be omitted from or shown in a simplified form in the figures or otherwise summarized.

For purposes of explanation, numerous details are set forth in order to provide a thorough understanding of the present disclosure. It should be appreciated, however, that the present disclosure may be practiced in a variety of ways beyond the specific details set forth herein.

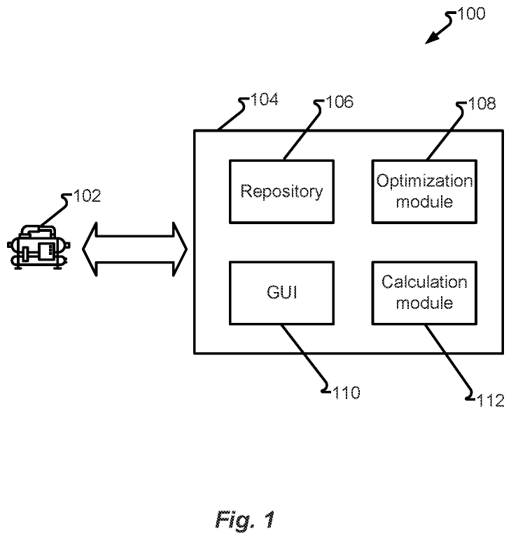

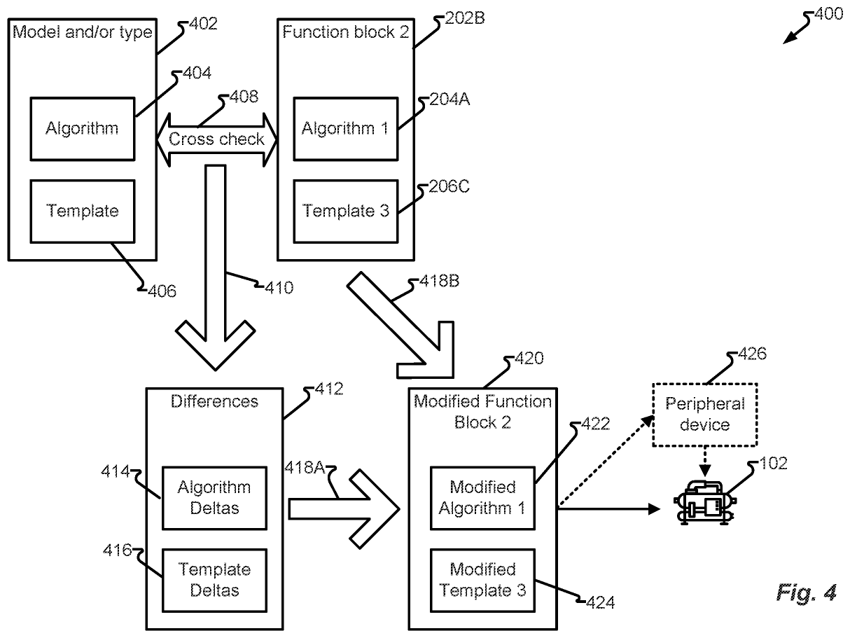

FIG. 1 depicts system 100 in accordance with embodiments of the present disclosure. System 100 comprises asset 102 providing data outputs to subsystem 104 and/or receiving control inputs from subsystem 104. The interaction between asset 102 and subsystem 104 may be direct or comprise a peripheral device, such as peripheral device 426 (see FIG. 4).

Subsystem 104 may be executed on a single computing device (e.g., laptop, personal computer, smart device, etc.) or distributed across multiple computing devices (e.g., array, server farm, computational “cloud”, etc.). It should be appreciated that while subsystem 104 is illustrated as a single element, in other embodiments, subsystem 104 may comprise a plurality of elements, such as to execute one or more of repository 106, optimization module 108, graphical user interface (GUI) 110, and calculation module 112.

Repository 106 may be embodied as a computer memory or data storage device operable to maintain accessible data records, such as function blocks, algorithms, mappings, etc., which are discussed more completely with respect to embodiments to follow. Additional data storage, such as computer memory or other data records, may be provided by other storage devices (not shown).

In another embodiment, GUI 110 displays information and/or receives user inputs via an input-output device. GUI 110 may display for selection the particular asset (e.g., asset 102) or a category of assets, of which asset 102 may be a member. It should be appreciated that only a single asset (i.e., asset 102) is illustrated to avoid unnecessarily complicating the figures and descriptions thereof. The embodiments described herein may apply to a number of assets without departing from the scope of the embodiments provided. Additionally, certain embodiments herein may apply to a number of the same type of assets (e.g., a collection of chillers) while certain other embodiments may apply to one or more assets of a dissimilar type (e.g., one chiller and three compressors, two solar arrays and four evaporators, etc.).

In another embodiment, optimization module 108 determines an optimum operation parameter for asset 102. Optimization module 108 may be further embodied as a peripheral device configured to monitor a performance attribute of asset 102. As will be described more completely with respect to embodiments that follow, optimization may comprise selecting a function block, associated algorithms, and mappings between selected data inputs and corresponding data outputs. The data outputs may be key performance indicators (KPIs) for the expected and/or observed output of asset 102.

In another embodiment, calculation module 112 provides data processing and/or other computational operations. Calculation module 112 may be utilized to perform the KPI calculations that are then provided to optimization module 108.

Subsystem 104 and/or one or more components thereof (e.g., repository 106, optimization module 108, GUI 110, calculation module 112) may comprise or access a network interface to a network, such as to communicate with asset 102 and/or other components.

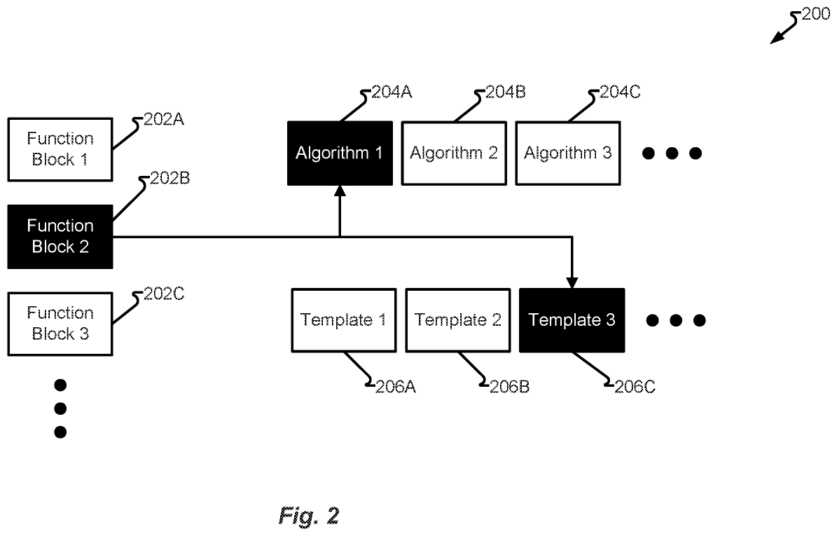

FIG. 2 depicts data flow 200 in accordance with embodiments of the present disclosure. Asset 102 may be associated with one or more functional blocks. For example, asset 102 may be associated with function block 1 (202A), function block 2 (202B), function block 3 (202C), and optionally additional function blocks. The selection of one function block, such as function block 2 (202B) is made (shown highlighted in FIG. 2).

One or more algorithms, such as algorithm 1 (204A), algorithm 2 (204B), algorithm 3 (204C), and/or additional algorithms are available and may be predefined algorithms. Each algorithm utilizes different logic and/or data inputs to determine KPIs. Additionally, one or more templates, such as template 1 (206A), template 2 (206B), template 3 (206C), and/or additional templates are available. The selection of a particular function block (e.g., function block 2 (202B)) then automatically selects an algorithm (e.g., algorithm 1 (204A) illustrated as highlighted) and a template (e.g., template 3 (206C) illustrated as highlighted).

As used herein, a function block maintains one or more templates for different assets and/or asset types. A function block template library may be provided to maintain templates/targeted operation templates for different types of targeted devices such as an assets (e.g., chillers, solar collectors/concentrators, compressors, etc.).

As used herein, an algorithm is a pre-defined set of rules that, when executed by a machine (e.g., processor) cause the machine to generate an output parameter, such as a KPI. The selection of one algorithm may select that algorithm alone, select one or more additional algorithms that produce independent results (e.g., different KPIs), or select one or more nested or cascading algorithms (e.g., selecting a “power consumption” algorithm selects a “voltage over time” algorithm to generate a portion of the “power consumption” algorithm).

As used herein, a template is created by automatically mapping between input parameters (e.g., the inputs for KPI calculations such as measurement data from sensors/devices etc.) and output parameters (e.g., the KPIs). For example, the selection of a particular template, such as “chiller” from the function block template library, causes the automatic selection of the relevant input parameters and mappings to the relevant output parameters or KPIs, such as power consumption.

Upon selection of function block 2 (202B), one of one or more algorithms is automatically selected, such as algorithm 1 (204A) due to a mapping (discussed below).

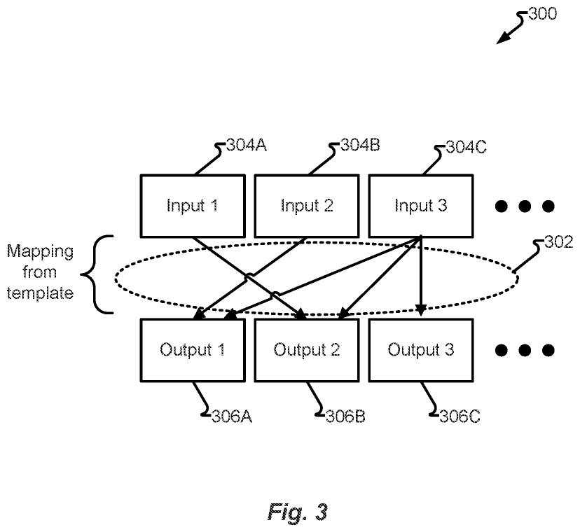

FIG. 3 depicts data flow 300 in accordance with embodiments of the present disclosure. Data flow 300 maps inputs, such as input 1 (304A), input 2 (304B), input 3 (304C), etc., to specific outputs, such as output 1 (306A), output 2 (306B), output 3 (306C), etc. For the avoidance of confusion, reference to inputs and outputs herein refers to datum/data inputs and resulting KPIs, respectively, and not to the production inputs or outputs themselves that may be provided to and produced from an asset.

There may be a large number of inputs available to calculate the operation of asset 102. Not all available inputs will be relevant to a particular asset or asset type and/or a particular utilization of such an asset. The use of such irrelevant data is, at best, a waste of computational resources and may even lead to the determination of erroneous KPIs. For example, a temperature of a production input may be critical to the operation of the asset when producing one product, but irrelevant to producing another. Accordingly, mapping 302 is provided that associates individual inputs 304 or groups of inputs 304 to individual outputs 306 or groups of outputs 306. It should be appreciated that, in some embodiments, any one input may be used for a plurality of outputs and vice versa. In other embodiments, at least one input and/or at least one output may be unused.

FIG. 4 depicts data flow 400 in accordance with embodiments of the present disclosure. Data flow 400 illustrates the optimization of the operation of asset 102. In one embodiment, a model (i.e., a specific asset) and/or type of asset is selected by selecting a function block, such as function block 2 (202B). Once function block 2 (202B) is selected, associated algorithm 1 (204A) and template 3 (206C) are then automatically selected. Algorithms, such as algorithm 1 (204A) is a pre-defined algorithm for controlling and/or maintaining asset 102.

Cross check 408 compares function block 2 (202B) to one or more of a model indicator and type indicator block 402, such as to confirm a match between algorithm 1 (204A) and algorithm 404 and between template 3 (206C) and template 406. Differences 410, if any, are determined and provided to block 412, comprising algorithm deltas 414 and/or template deltas 416. When differences are non-null, modified function block 2 (420) may be generated from accessing deltas 418A and accessing 418B original function block 2 (202B). As a result, modified algorithm 1 (422) and/or modified template 3 (424) may be produced and applied to asset 102 either directly or via peripheral device 426.

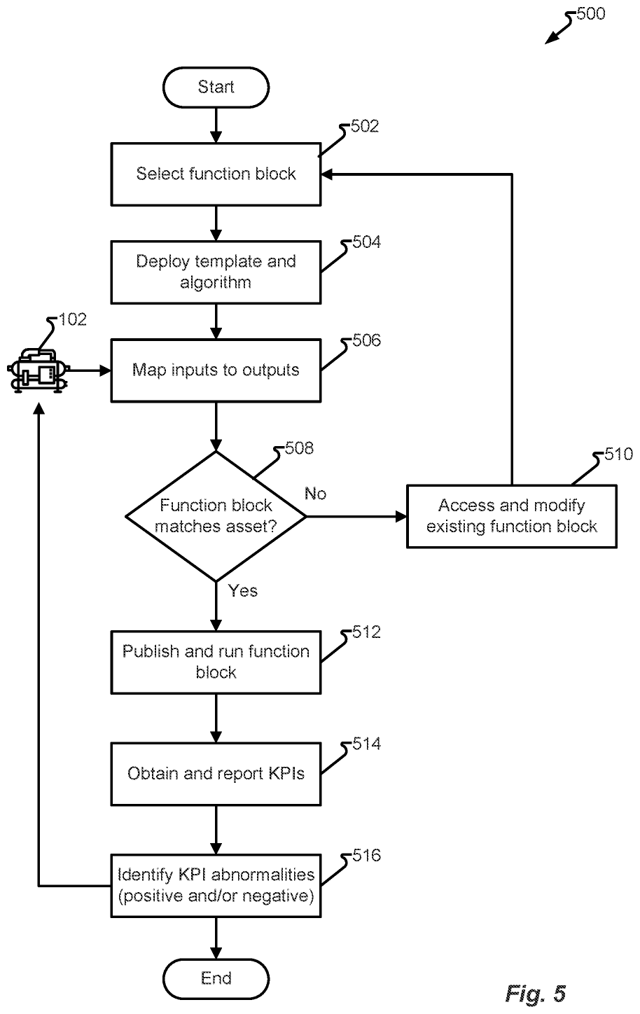

FIG. 5 depicts process 500 in accordance with embodiments of the present disclosure. In one embodiment, process 500 is embodied as machine-readable instructions maintained in a non-transitory memory that when read by a machine, such as a processor of a server, cause the machine to execute the instructions and thereby execute process 500.

Process 500 begins and, in step 502, a function block is selected, such as one of function blocks 202 (see FIG. 2). Step 504 deploys the corresponding template and algorithm such as a particular template 206 (Id.) and algorithm 204 (Id.). Inputs are mapped to outputs in step 506, such as to obtain a number of data from asset 102 and/or from other sources (e.g., peripheral device 426, see FIG. 4; other assets, etc.).

Test 508 determines if the function block matches the asset. If test 508 is determined in the negative, step 510 accesses and modifies the existing function block in accordance with the differences determined in test 508. If test 508 is determined in the affirmative, processing continues to step 512. Step 512 publishes (e.g., propagates to asset 102) and runs the function block. Step 514 obtains or otherwise determines KPIs which may then be reported, such as to calculate module 112 and/or another component. Step 516 then identifies any abnormalities between observed data and the KPIs predicted, and asset 102 may be operated accordingly, such as to attenuate such differences, and then process 500 may end.

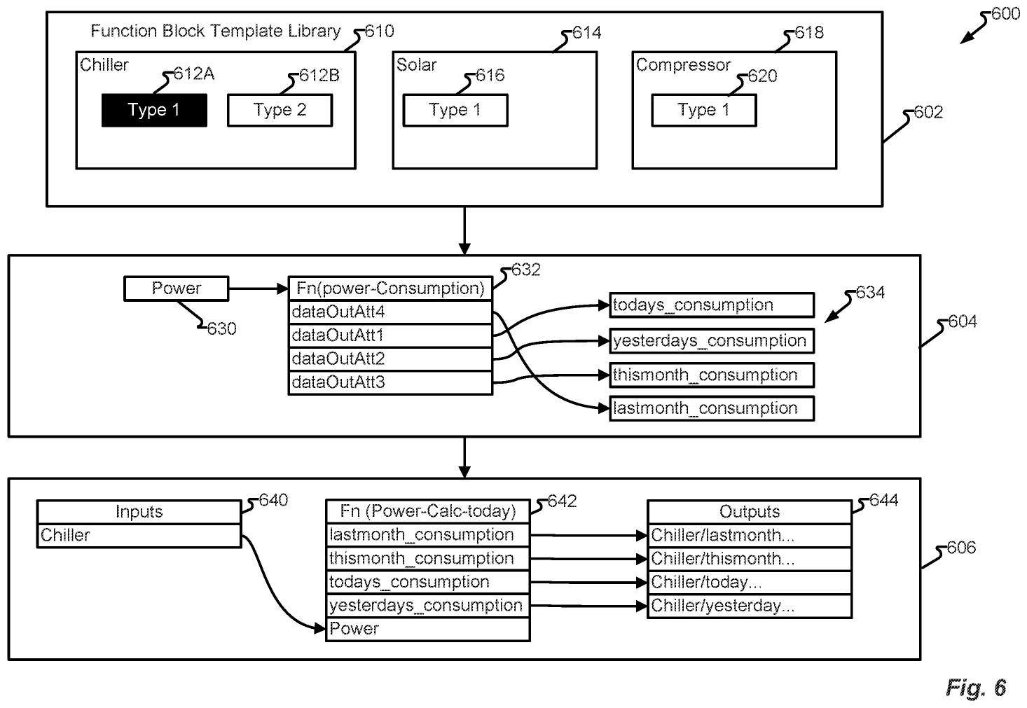

FIG. 6 depicts graphical user interface (GUI) 600 in accordance with embodiments of the present disclosure. GUI 600 may present outputs and/or receive inputs from a human, such as via an input-output device. Function block template library 602 presents a number of function blocks in accordance with a type of asset, such as chiller 610, solar collector 614, and compressor 618. If more than one type of asset (e.g., different model, different features, different configuration, etc.) is available, a corresponding more than one type is presented, such as type 1 (612A) and type 2 (612B). In contrast, solar collector 614 has a single option, type 1 (616), and, similarly, compressor 618 has type 1 (620).

As an example, type 1 (612A) is selected (illustrated as highlighted) and, accordingly, function block template/targeted operation template 604 is selected. Function block template/targeted operation template 604 comprises inputs (e.g., inputs from a sensor associated with the asset, inputs from a device associated with the asset, inputs from a system associated with the asset, etc.) and outputs (e.g., algorithmically calculated KPIs). For example, power 630 comprises algorithms 632 and produces outputs 634.

Next, mapping 606 maps the inputs to the outputs, such as inputs 640, via algorithms 642, and then to outputs 644.

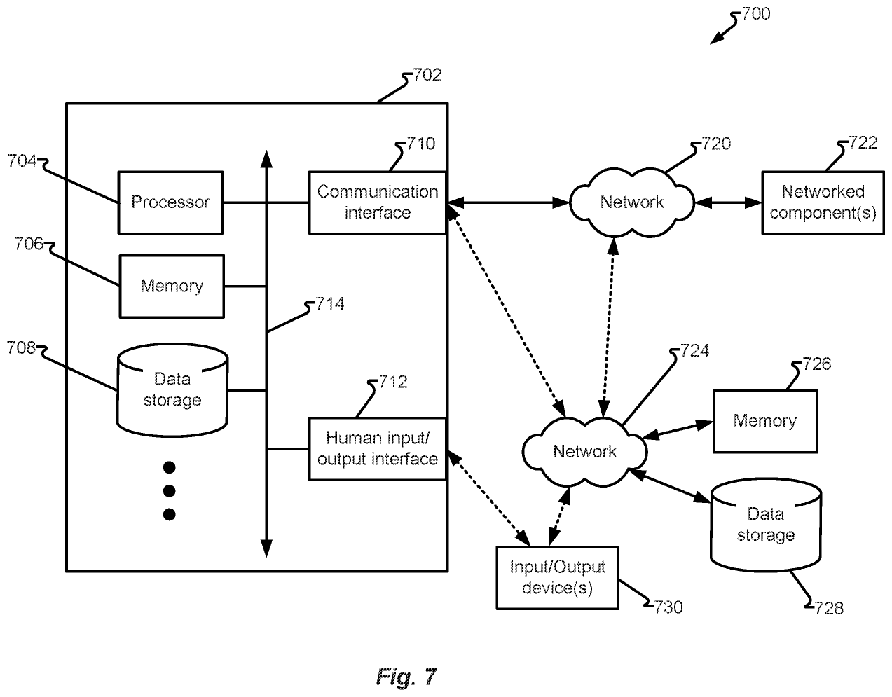

FIG. 7 depicts system 700 in accordance with embodiments of the present disclosure. In one embodiment, device 702 comprising various components and connections to other components and/or systems to execute certain embodiments described herein. The components are variously embodied and may comprise processor 704. The term “processor,” as used herein, refers exclusively to electronic hardware components comprising electrical circuitry with connections (e.g., pin-outs) to convey encoded electrical signals to and from the electrical circuitry. Processor 704 may comprise programmable logic functionality, such as determined, at least in part, from accessing machine-readable instructions maintained in a non-transitory data storage, which may be embodied as circuitry, on-chip read-only memory, computer memory 706, data storage 708, etc., that cause the processor 704 to perform the steps of the instructions. Processor 704 may be further embodied as a single electronic microprocessor or multiprocessor device (e.g., multicore) having electrical circuitry therein which may further comprise a control unit(s), input/output unit(s), arithmetic logic unit(s), register(s), primary memory, and/or other components that access information (e.g., data, instructions, etc.), such as received via bus 714, executes instructions, and outputs data, again such as via bus 714. In other embodiments, processor 704 may comprise a shared processing device that may be utilized by other processes and/or process owners, such as in a processing array within a system (e.g., blade, multi-processor board, etc.) or distributed processing system (e.g., “cloud”, farm, etc.). It should be appreciated that processor 704 is a non-transitory computing device (e.g., electronic machine comprising circuitry and connections to communicate with other components and devices). Processor 704 may operate a virtual processor, such as to process machine instructions not native to the processor (e.g., translate the VAX operating system and VAX machine instruction code set into Intel® 9xx chipset code to enable VAX-specific applications to execute on a virtual VAX processor). However, as those of ordinary skill understand, such virtual processors are applications executed by hardware, more specifically, the underlying electrical circuitry and other hardware of the processor (e.g., processor 704). Processor 704 may be executed by virtual processors, such as when applications (i.e., Pod) are orchestrated by Kubernetes. Virtual processors enable an application to be presented with what appears to be a static and/or dedicated processor executing the instructions of the application, while underlying non-virtual processor(s) are executing the instructions and may be dynamic and/or split among a number of processors.

In addition to the components of processor 704, device 702 may utilize computer memory 706 and/or data storage 708 for the storage of accessible data, such as instructions, values, etc. Communication interface 710 facilitates communication with components, such as processor 704 via bus 714 with components not accessible via bus 714. Communication interface 710 may be embodied as a network port, card, cable, or other configured hardware device. Additionally or alternatively, human input/output interface 712 connects to one or more interface components to receive and/or present information (e.g., instructions, data, values, etc.) to and/or from a human and/or electronic device. Examples of input/output devices 730 that may be connected to input/output interface include, but are not limited to, keyboard, mouse, trackball, printers, displays, sensor, switch, relay, speaker, microphone, still and/or video camera, etc. In another embodiment, communication interface 710 may comprise, or be comprised by, human input/output interface 712. Communication interface 710 may be configured to communicate directly with a networked component or configured to utilize one or more networks, such as network 720 and/or network 724.

Network 720 may be a wired network (e.g., Ethernet), wireless (e.g., WiFi, Bluetooth, cellular, etc.) network, or combination thereof and enable device 702 to communicate with networked component(s) 722. In other embodiments, network 720 may be embodied, in whole or in part, as a telephony network (e.g., public switched telephone network (PSTN), private branch exchange (PBX), cellular telephony network, etc.).

Additionally or alternatively, one or more other networks may be utilized. For example, network 724 may represent a second network, which may facilitate communication with components utilized by device 702. For example, network 724 may be an internal network to a business entity or other organization, whereby components are trusted (or at least more so) than networked components 722, which may be connected to network 720 comprising a public network (e.g., Internet) that may not be as trusted.

Components attached to network 724 may include computer memory 726, data storage 728, input/output device(s) 730, and/or other components that may be accessible to processor 704. For example, computer memory 726 and/or data storage 728 may supplement or supplant computer memory 706 and/or data storage 708 entirely or for a particular task or purpose. As another example, computer memory 726 and/or data storage 728 may be an external data repository (e.g., server farm, array, “cloud,” etc.) and enable device 702, and/or other devices, to access data thereon. Similarly, input/output device(s) 730 may be accessed by processor 704 via human input/output interface 712 and/or via communication interface 710 either directly, via network 724, via network 720 alone (not shown), or via networks 724 and 720. Each of computer memory 706, data storage 708, computer memory 726, data storage 728 comprise a non-transitory data storage comprising a data storage device.

It should be appreciated that computer readable data may be sent, received, stored, processed, and presented by a variety of components. It should also be appreciated that components illustrated may control other components, whether illustrated herein or otherwise. For example, one input/output device 730 may be a router, a switch, a port, or other communication component such that a particular output of processor 704 enables (or disables) input/output device 730, which may be associated with network 720 and/or network 724, to allow (or disallow) communications between two or more nodes on network 720 and/or network 724. One of ordinary skill in the art will appreciate that other communication equipment may be utilized, in addition or as an alternative, to those described herein without departing from the scope of the embodiments.

In the foregoing description, for the purposes of illustration, methods were described in a particular order. It should be appreciated that in alternate embodiments, the methods may be performed in a different order than that described without departing from the scope of the embodiments. It should also be appreciated that the methods described above may be performed as algorithms executed by hardware components (e.g., circuitry) purpose-built to carry out one or more algorithms or portions thereof described herein. In another embodiment, the hardware component may comprise a general-purpose microprocessor (e.g., CPU, GPU) that is first converted to a special-purpose microprocessor. The special-purpose microprocessor then having had loaded therein encoded signals causing the, now special-purpose, microprocessor to maintain machine-readable instructions to enable the microprocessor to read and execute the machine-readable set of instructions derived from the algorithms and/or other instructions described herein. The machine-readable instructions utilized to execute the algorithm(s), or portions thereof, are not unlimited but utilize a finite set of instructions known to the microprocessor. The machine-readable instructions may be encoded in the microprocessor as signals or values in signal-producing components by, in one or more embodiments, voltages in memory circuits, configuration of switching circuits, and/or by selective use of particular logic gate circuits. Additionally or alternatively, the machine-readable instructions may be accessible to the microprocessor and encoded in a media or device as magnetic fields, voltage values, charge values, reflective/non-reflective portions, and/or physical indicia.

In another embodiment, the microprocessor further comprises one or more of a single microprocessor, a multi-core processor, a plurality of microprocessors, a distributed processing system (e.g., array(s), blade(s), server farm(s), “cloud”, multi-purpose processor array(s), cluster(s), etc.) and/or may be co-located with a microprocessor performing other processing operations. Any one or more microprocessors may be integrated into a single processing appliance (e.g., computer, server, blade, etc.) or located entirely, or in part, in a discrete component and connected via a communications link (e.g., bus, network, backplane, etc. or a plurality thereof).

Examples of general-purpose microprocessors may comprise, a central processing unit (CPU) with data values encoded in an instruction register (or other circuitry maintaining instructions) or data values comprising memory locations, which in turn comprise values utilized as instructions. The memory locations may further comprise a memory location that is external to the CPU. Such CPU-external components may be embodied as one or more of a field-programmable gate array (FPGA), read-only memory (ROM), programmable read-only memory (PROM), erasable programmable read-only memory (EPROM), random access memory (RAM), bus-accessible storage, network-accessible storage, etc.

These machine-executable instructions may be stored on one or more machine-readable mediums, such as CD-ROMs or other type of optical disks, floppy diskettes, ROMs, RAMS, EPROMs, EEPROMs, magnetic or optical cards, flash memory, or other types of machine-readable mediums suitable for storing electronic instructions. Alternatively, the methods may be performed by a combination of hardware and software.

In another embodiment, a microprocessor may be a system or collection of processing hardware components, such as a microprocessor on a client device and a microprocessor on a server, a collection of devices with their respective microprocessor, or a shared or remote processing service (e.g., “cloud” based microprocessor). A system of microprocessors may comprise task-specific allocation of processing tasks and/or shared or distributed processing tasks. In yet another embodiment, a microprocessor may execute software to provide the services to emulate a different microprocessor or microprocessors. As a result, a first microprocessor, comprised of a first set of hardware components, may virtually provide the services of a second microprocessor whereby the hardware associated with the first microprocessor may operate using an instruction set associated with the second microprocessor.

While machine-executable instructions may be stored and executed locally to a particular machine (e.g., personal computer, mobile computing device, laptop, etc.), it should be appreciated that the storage of data and/or instructions and/or the execution of at least a portion of the instructions may be provided via connectivity to a remote data storage and/or processing device or collection of devices, commonly known as “the cloud,” but may include a public, private, dedicated, shared and/or other service bureau, computing service, and/or “server farm.”

Examples of the microprocessors as described herein may include, but are not limited to, at least one of Qualcomm® Snapdragon® 800 and 801, Qualcomm® Snapdragon® 610 and 615 with 4G LTE Integration and 64-bit computing, Apple® A7 microprocessor with 64-bit architecture, Apple® M7 motion comicroprocessors, Samsung® Exynos® series, the Intel® Core™ family of microprocessors, the Intel® Xeon® family of microprocessors, the Intel® Atom™ family of microprocessors, the Intel Itanium® family of microprocessors, Intel® Core® i5-4670K and i7-4770K 22 nm Haswell, Intel® Core® i5-3570K 22 nm Ivy Bridge, the AMD® FX™ family of microprocessors, AMD® FX-4300, FX-6300, and FX-8350 32 nm Vishera, AMD® Kaveri microprocessors, Texas Instruments® Jacinto C6000™ automotive infotainment microprocessors, Texas Instruments® OMAP™ automotive-grade mobile microprocessors, ARM® Cortex™_M microprocessors, ARM® Cortex-A and ARM926EJ-S™ microprocessors, other industry-equivalent microprocessors, and may perform computational functions using any known or future-developed standard, instruction set, libraries, and/or architecture.

Any of the steps, functions, and operations discussed herein can be performed continuously and automatically.

The exemplary systems and methods of this invention have been described in relation to communications systems and components and methods for monitoring, enhancing, and embellishing communications and messages. However, to avoid unnecessarily obscuring the present invention, the preceding description omits a number of known structures and devices. This omission is not to be construed as a limitation of the scope of the claimed invention. Specific details are set forth to provide an understanding of the present invention. It should, however, be appreciated that the present invention may be practiced in a variety of ways beyond the specific detail set forth herein.

Furthermore, while the exemplary embodiments illustrated herein show the various components of the system collocated, certain components of the system can be located remotely, at distant portions of a distributed network, such as a LAN and/or the Internet, or within a dedicated system. Thus, it should be appreciated, that the components or portions thereof (e.g., microprocessors, memory/storage, interfaces, etc.) of the system can be combined into one or more devices, such as a server, servers, computer, computing device, terminal, “cloud” or other distributed processing, or collocated on a particular node of a distributed network, such as an analog and/or digital telecommunications network, a packet-switched network, or a circuit-switched network. In another embodiment, the components may be physical or logically distributed across a plurality of components (e.g., a microprocessor may comprise a first microprocessor on one component and a second microprocessor on another component, each performing a portion of a shared task and/or an allocated task). It will be appreciated from the preceding description, and for reasons of computational efficiency, that the components of the system can be arranged at any location within a distributed network of components without affecting the operation of the system. For example, the various components can be located in a switch such as a PBX and media server, gateway, in one or more communications devices, at one or more users' premises, or some combination thereof. Similarly, one or more functional portions of the system could be distributed between a telecommunications device(s) and an associated computing device.

Furthermore, it should be appreciated that the various links connecting the elements can be wired or wireless links, or any combination thereof, or any other known or later developed element(s) that is capable of supplying and/or communicating data to and from the connected elements. These wired or wireless links can also be secure links and may be capable of communicating encrypted information. Transmission media used as links, for example, can be any suitable carrier for electrical signals, including coaxial cables, copper wire, and fiber optics, and may take the form of acoustic or light waves, such as those generated during radio-wave and infra-red data communications.

Also, while the flowcharts have been discussed and illustrated in relation to a particular sequence of events, it should be appreciated that changes, additions, and omissions to this sequence can occur without materially affecting the operation of the invention.

A number of variations and modifications of the invention can be used. It would be possible to provide for some features of the invention without providing others.

In yet another embodiment, the systems and methods of this invention can be implemented in conjunction with a special purpose computer, a programmed microprocessor or microcontroller and peripheral integrated circuit element(s), an ASIC or other integrated circuit, a digital signal microprocessor, a hard-wired electronic or logic circuit such as discrete element circuit, a programmable logic device or gate array such as PLD, PLA, FPGA, PAL, special purpose computer, any comparable means, or the like. In general, any device(s) or means capable of implementing the methodology illustrated herein can be used to implement the various aspects of this invention. Exemplary hardware that can be used for the present invention includes computers, handheld devices, telephones (e.g., cellular, Internet enabled, digital, analog, hybrids, and others), and other hardware known in the art. Some of these devices include microprocessors (e.g., a single or multiple microprocessors), memory, nonvolatile storage, input devices, and output devices. Furthermore, alternative software implementations including, but not limited to, distributed processing or component/object distributed processing, parallel processing, or virtual machine processing can also be constructed to implement the methods described herein as provided by one or more processing components.

In yet another embodiment, the disclosed methods may be readily implemented in conjunction with software using object or object-oriented software development environments that provide portable source code that can be used on a variety of computer or workstation platforms. Alternatively, the disclosed system may be implemented partially or fully in hardware using standard logic circuits or VLSI design. Whether software or hardware is used to implement the systems in accordance with this invention is dependent on the speed and/or efficiency requirements of the system, the particular function, and the particular software or hardware systems or microprocessor or microcomputer systems being utilized.

In yet another embodiment, the disclosed methods may be partially implemented in software that can be stored on a storage medium, executed on programmed general-purpose computer with the cooperation of a controller and memory, a special purpose computer, a microprocessor, or the like. In these instances, the systems and methods of this invention can be implemented as a program embedded on a personal computer such as an applet, JAVA® or CGI script, as a resource residing on a server or computer workstation, as a routine embedded in a dedicated measurement system, system component, or the like. The system can also be implemented by physically incorporating the system and/or method into a software and/or hardware system.

Embodiments herein comprising software are executed, or stored for subsequent execution, by one or more microprocessors and are executed as executable code. The executable code being selected to execute instructions that comprise the particular embodiment. The instructions executed being a constrained set of instructions selected from the discrete set of native instructions understood by the microprocessor and, prior to execution, committed to microprocessor-accessible memory. In another embodiment, human-readable “source code” software, prior to execution by the one or more microprocessors, is first converted to system software to comprise a platform (e.g., computer, microprocessor, database, etc.) specific set of instructions selected from the platform's native instruction set.

Although the present invention describes components and functions implemented in the embodiments with reference to particular standards and protocols, the invention is not limited to such standards and protocols. Other similar standards and protocols not mentioned herein are in existence and are considered to be included in the present invention. Moreover, the standards and protocols mentioned herein and other similar standards and protocols not mentioned herein are periodically superseded by faster or more effective equivalents having essentially the same functions. Such replacement standards and protocols having the same functions are considered equivalents included in the present invention.

The present invention, in various embodiments, configurations, and aspects, includes components, methods, processes, systems and/or apparatus substantially as depicted and described herein, including various embodiments, subcombinations, and subsets thereof. Those of skill in the art will understand how to make and use the present invention after understanding the present disclosure. The present invention, in various embodiments, configurations, and aspects, includes providing devices and processes in the absence of items not depicted and/or described herein or in various embodiments, configurations, or aspects hereof, including in the absence of such items as may have been used in previous devices or processes, e.g., for improving performance, achieving ease, and/or reducing cost of implementation.

The foregoing discussion of the invention has been presented for purposes of illustration and description. The foregoing is not intended to limit the invention to the form or forms disclosed herein. In the foregoing Detailed Description for example, various features of the invention are grouped together in one or more embodiments, configurations, or aspects for the purpose of streamlining the disclosure. The features of the embodiments, configurations, or aspects of the invention may be combined in alternate embodiments, configurations, or aspects other than those discussed above. This method of disclosure is not to be interpreted as reflecting an intention that the claimed invention requires more features than are expressly recited in each claim. Rather, as the following claims reflect, inventive aspects lie in less than all features of a single foregoing disclosed embodiment, configuration, or aspect. Thus, the following claims are hereby incorporated into this Detailed Description, with each claim standing on its own as a separate preferred embodiment of the invention.

Moreover, though the description of the invention has included description of one or more embodiments, configurations, or aspects and certain variations and modifications, other variations, combinations, and modifications are within the scope of the invention, e.g., as may be within the skill and knowledge of those in the art, after understanding the present disclosure. It is intended to obtain rights, which include alternative embodiments, configurations, or aspects to the extent permitted, including alternate, interchangeable and/or equivalent structures, functions, ranges, or steps to those claimed, whether or not such alternate, interchangeable and/or equivalent structures, functions, ranges, or steps are disclosed herein, and without intending to publicly dedicate any patentable subject matter.

What is claimed is:

1. A method of monitoring an asset, comprising:
accessing a database of devices, wherein the database comprises a plurality of templates, and wherein each of the plurality of templates comprises an asset type related information and a plurality of predefined algorithms;
providing a graphical user interface for a user to input information related to a targeted device;
automatically selecting a targeted operation template among the plurality of templates for the asset in response to either the input information or a change of condition of a neighboring device connected to the targeted device;
automatically modifying one of the plurality of predefined algorithms that is associated with the targeted operation template based on a peripheral device associated with the asset for an optimization purpose; and
calculating asset performance indicators as a measure to determine how far the optimization purpose has been achieved.

2. The method of claim 1, wherein the asset type comprises an industrial component.

3. The method of claim 2, wherein the industrial component comprises a controllable physical portion further comprising at least one of a motor, an actuator, a magnetic field generator, and an electrical current generator.

4. The method of claim 2, wherein the industrial component comprises at least one of a chiller, a pump, a boiler, a blower, and a compressor.

5. The method of claim 1, wherein each of the plurality of predefined algorithms is associated with a plurality of parameters comprising at least one of: chiller power, chilled water supply temperature, chilled water return temperature, or chilled water flow, when the asset type is a chiller.

6. The method of claim 1, wherein at least two of the plurality of predefined algorithms is associated with a plurality of parameters comprising at least one of: discharge pressure, discharge flow, wet well level, and pump power, when the asset type is a pump.

7. The method of claim 1, wherein automatically modifying one of the plurality of predefined algorithms that is associated with the targeted operation template comprises: selecting a sub-set of predefined algorithms among the plurality of predefined algorithms, and automatically combining the sub-set of predefined algorithms to form a combined algorithm, wherein the combined algorithm is associated with performance of a second asset, wherein the second asset is associated with the asset.

8. The method of claim 7, wherein selecting a sub-set of predefined algorithms among the plurality of predefined algorithms comprises: identifying one or more correlations among the plurality of predefined algorithms, and selecting a sub-set of predefined algorithms bases on the one or more correlations, wherein the sub-set of predefined algorithms are correlated.

9. The method of claim 1, wherein the peripheral device comprises at least one of: a sensor associated with the asset, an instrument associated with the asset, an algorithm associated with the asset, cloud data associated with the asset, or server data associated with the asset, and wherein the peripheral device provides a plurality of values associated with a plurality of parameters of the asset.

10. The method of claim 9, wherein automatically modifying one of the plurality of predefined algorithms that is associated with the targeted operation template comprises: obtaining the plurality of values associated with the plurality of parameters of the asset from the peripheral device, identifying one or more correlations among the plurality of parameters, and modifying one or more coefficients associated with the plurality of predefined algorithms based on the one or more correlations and the plurality of values.

11. The method of claim 1, further comprising:
receiving, via the graphical user interface, a user input associated with grouping a plurality of devices; and
assigning the plurality of devices to the asset based on the user input.

12. A system, comprising:
an input component to receive the selection of a function block from a number of function blocks;
a processor to, in accordance with the selection of the function block, automatically select a template, from a number of templates, and an algorithm, from a number of algorithms, wherein the template maps data inputs to the algorithm to outputs produced by the algorithm;
upon determining a difference between at least one of the template and the algorithm, to at least one of an asset-specific template or an asset-specific algorithm, modifying the corresponding at least one template or algorithm of the function block; and
the processor then causing an industrial asset to be operated in accordance with the function block.

13. The system of claim 12, further comprising:
a peripheral device in communication with the industrial asset; and
wherein the processor is a portion of the peripheral device.

14. A method, comprising:
receiving a selection of a function block for an asset;
selecting a template and a predefined algorithm for controlling and maintaining the asset based on receiving the selection of the function block for the asset;
mapping an input to the asset with output data for the asset;
cross-checking the function block to at least one of a model indicator and type indicator to confirm that the function block matches the selected template and the selected predefined algorithm; and
modifying the function block to better fit the asset based on the cross-checking.

15. The method of claim 14, wherein the asset comprises at least one of a chiller, pump, boiler, blower, and compressor.

16. The method of claim 14, further comprising:
confirming the modified function block better matches at least one Key Performance Indicator (KPI) of the asset as compared to the function block prior to modifying the function block; and
storing the modified function block in a database with an association that links the modified function block to the function block.

17. The method of claim 16, wherein the at least one KPI comprises at least one of pressure, discharge flow, wet well level, power, energy consumption value, and carbon dioxide emissions.

18. The method of claim 16, further comprising:
populating a user dashboard with a KPI of the asset according to at least one of the function block and the modified function block; and
receiving a user input via the dashboard, wherein the user input indicates which of the function block and modified function block is preferred to use in connection with the asset.

19. The method of claim 14, wherein the function block is selected from a function block template library that stores a plurality of templates for a plurality of different assets and asset types.

20. The method of claim 14, wherein the function block is displayed via a user interface along with one or more automatically-suggested input parameters for the asset.
